(19) United States
(12) Patent Application Publication
(10) Pub. No.: US 2002/0196612 A1
(43) Pub. Date: Dec. 26, 2002

(54) Arrangement of memory chip housings on a DIMM circuit board

(76) Inventors: Martin Gall, Muenchen (DE); Simon Muff, Hoehenkirchen (DE); Wolfgang Hoppe, Bad Toelz (DE)

Correspondence Address: Frank Chau, F. CHAU & ASSOCIATES, LLP, Suite 501, 1900 Hempstead Turnpike, East Meadow, NY, 11554, US

(21) Appl. No.: 10/155,847

(22) Filed: May 24, 2002

(30) Foreign Application Priority Data
May 25, 2001 (DE) DE 201 08 758.8

(51) Int. Cl. H05K 7/02; H05K 7/06; H05K 7/08; H05K 7/10

(52) U.S. Cl. 361/760

(57) ABSTRACT

The invention relates to the arrangement of a plurality of memory chip housings, each having at least one memory chip arranged in the interior of the memory chip housing and having a plurality of pins, which are led out of the respective memory chip housing, on a DIMM circuit board which, on one long side, has a multipole contact rail for insertion into a base of a mother board, where the plurality of memory chip housings (2) [lacuna] arranged in two rows (6, 7) parallel to the long side (3) of the circuit board (1).

The invention relates to the arrangement of memory chip housings on a DIMM circuit board.

In the case of conventional TSOP memory housings, in order to implement a 1 Gb dual inline memory module (DIMM), for example, the components have to be stacked on the circuit board, that is to say in each case two TSOP memory housings are arranged one above another, in order to be able to accommodate them on a circuit board of a predefined size.

Because of the further miniaturization and the requirements on the operating speed, more and more BGA (ball grid array) housings are being used. However, at the moment these cannot yet be stacked reliably and cost-effectively and can be arranged only side by side on the modular circuit board. If the memory components are placed side by side in a row, however, it is not possible to place more than nine components on one side of the circuit board. This means that when 256 Mb components are used and there is a maximum of nine components per side of the circuit board, it is therefore possible only for modules with a maximum storage capacity of 512 Mb to be produced.

It is an object of the present invention to increase the capacity of the memory module by means of an optimized chip arrangement.

The object is achieved by the arrangement according to claim 1. A preferred embodiment of the invention forms the subject of claim 2.

The invention is based on the idea of arranging a plurality of components on the module circuit board. As a result of increasing the module area, it is possible to place the components in two rows and therefore to accommodate more than ten components on the circuit board. This is possible with correspondingly small chips. Thus, for example, by using 256 Mb components, a 1 Gb memory module may be produced.

The arrangement according to the invention of a plurality of memory chip housings each having at least one memory chip arranged in the interior of the memory chip housing and having a plurality of pins, which are led out of the respective memory chip housing, on a circuit board which, on one long side, has a multipole contact rail for insertion into a base on a mother board, is characterized in that the plurality of memory chip housings are arranged in two rows parallel to the long side of the circuit board.

In particular, in the arrangement the plurality of memory chip housings can be arranged with their long side parallel to the long side of the circuit board.

The invention will be explained below by using two exemplary embodiments, reference being made to the appended drawings.

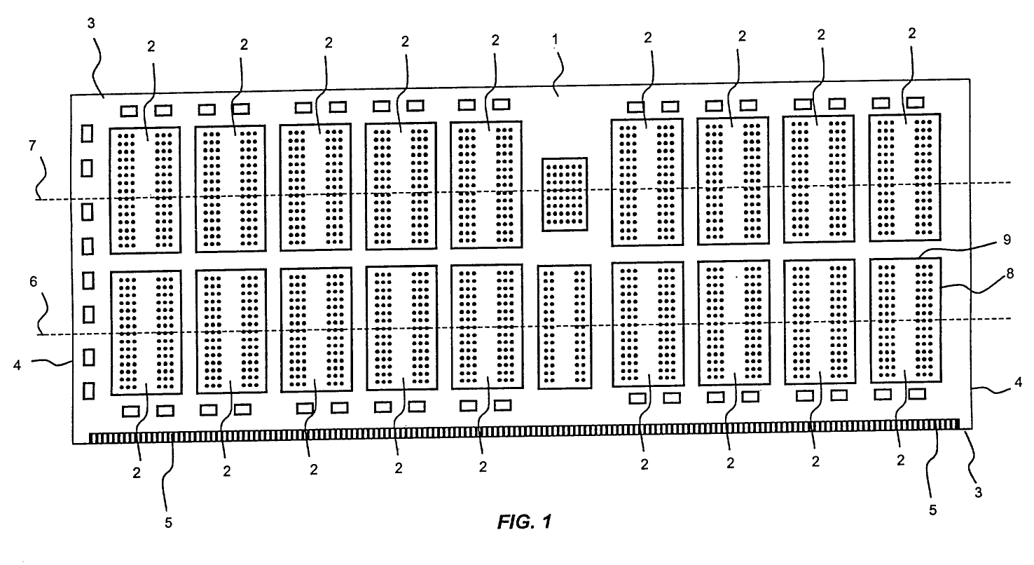

FIG. 1 shows the view of one side of a DIMM circuit board in a first embodiment of the invention.

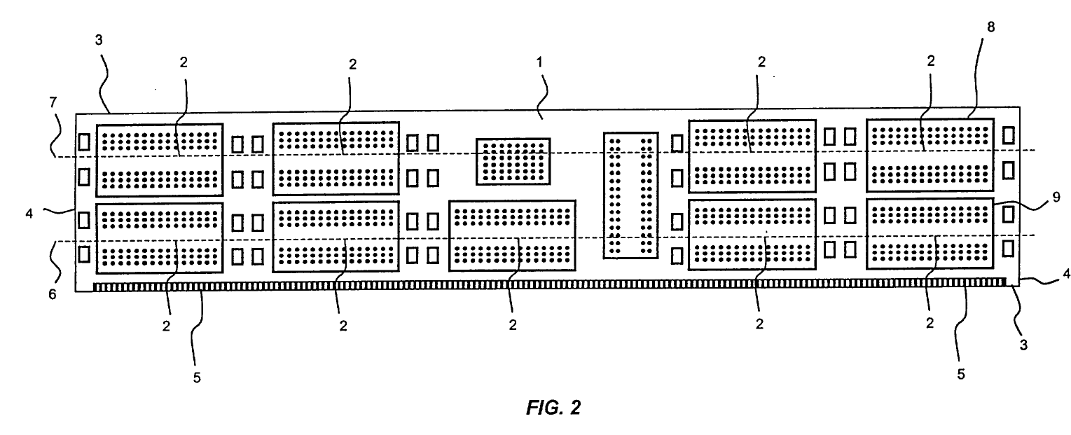

FIG. 2 shows the view of one side of a DIMM circuit board in a second embodiment of the invention.

FIG. 1 shows one side of a circuit board 1 of a dual inline memory module (DIMM). DIMM modules represent a particularly space-saving design of memory modules. The memory modules are chips which are accommodated in memory chip housings 2 having a plurality of pins. The pins are led out of the respective memory chip housing. The memory chip housings 2 are produced in two designs. In the first design, the pins are all led out on the narrow side of the housing (type I), and in the second design the pins are all led out on the long side of the housing (type II).

In the prior art, the memory chip housings 2 are arranged side by side in a row on the circuit board 1. The circuit board 1 is generally rectangular and has a long side 3 and a narrow side 4. On its long side 3, the circuit board 1 has a generally 168-pole contact rail 5, which can be inserted into a special base (not shown) of a mother board (not shown). The RAM components 2 on the circuit board 1 are driven with an address width of 64 bits.

In the arrangement according to the invention, the memory chip housings 2 are arranged on the circuit board 1 in two rows parallel to the long edge 3 of the circuit board 1. This means that they are arranged side by side (in pairs) not only in a first direction on the circuit board 1 but also in a second direction on the circuit board 1. (The first direction and the second direction on the circuit board are in this case at right angles to each other). The two rows are illustrated in FIG. 1 by dashed lines 6 and 7.

In the orientation of the memory chip housings 2 on the circuit board 1, the result is substantially two possibilities. In FIG. 1, the narrow side 9 of the housings 2 lies parallel to the long side 3 of the circuit board 1 and vice-versa. As opposed to this, the orientation of the memory chip housings 2 in the embodiment according to FIG. 2 is rotated through 90°. In the embodiment of the invention in FIG. 2, the memory chip housings 2 are arranged with their long side 8 parallel to the long side 3 of the circuit board 1. Their narrow side 9 is therefore arranged parallel to the narrow side 4 of the circuit board 1.

With the described arrangement of the memory chip housings 2 on a circuit board 1 in two rows, the increase in the memory size of a memory module when using CSP (chip size package) housings, BGA type (ball grid array) is achieved. However, the invention is not restricted to the embodiments illustrated. For example, the memory chip housings 2 on the circuit board 1 can also be arranged at an oblique angle to one of the edges 3 or 4 of the circuit board 1, preferably so that the housings 2 in one of the two rows form a first angle with one of the edges 3 or 4, and the housings in the second of the two rows form the corresponding negative angle (that is to say with opposite direction of rotation) with one of the edges 3 or 4. Furthermore, the invention is of course not restricted to two rows 6 and 7, instead three or more rows can also be provided, in which the housings 2 are arranged parallel to one of the edges 3 or 4 of the circuit board 1 or form an (alternating) angle with the edges.

List of reference symbols

| | |
|---|---|
| 1 | Circuit board |
| 2 | Memory chip housing |
| 3 | Long side of the circuit board |
| 4 | Narrow side of the circuit board |
| 5 | Contact rail of the circuit board |
| 6 | First row with memory chip housings |
| 7 | Second row with memory chip housings |
| 8 | Long side of the memory chip housings |
| 9 | Narrow side of the memory chip housings |

1. Arrangement of a plurality of memory chip housings, each having at least one memory chip arranged in the interior of the memory chip housing and having a plurality of pins, which are led out of the respective memory chip housing, on a circuit board which, on one long side, has a multipole contact rail for insertion into a base on a mother board, characterized in that the plurality of memory chip housings (2) are arranged in two rows (6, 7) parallel to the long side (3) of the circuit board (1).

2. Arrangement according to claim 1, characterized in that the plurality of memory chip housings (2) are arranged with their long side (8) parallel to the long side (3) of the circuit board (1).
